(19) United States
(12) Patent Application Publication
(10) Pub. No.: US 2019/0270281 A1
(43) Pub. Date: Sep. 5, 2019

(54) METAL-CARBON PARTICLE COMPOSITE MATERIAL AND METHOD FOR MANUFACTURING SAME

(71) Applicant: SHOWA DENKO K.K., Tokyo (JP)

(72) Inventor: Katumasa HIROSE, Tochigi (JP)

(73) Assignee: SHOWA DENKO K.K., Tokyo (JP)

(21) Appl. No.: 16/348,978

(22) PCT Filed: Sep. 26, 2017
(86) PCT No.: PCT/JP2017/034644

§ 371 Date: May 10, 2019

(30) Foreign Application Priority Data
Nov. 11, 2016 (JP) 2016-220386

(51) Int. Cl. B32B 15/16; B32B 15/01; H01L 23/373; B32B 15/20

(52) U.S. Cl. CPC B32B 15/16; B32B 15/01; H01L 23/3735; B32B 2307/302; B32B 2264/108; B32B 2255/06; B32B 2255/20; B32B 15/20

(57) ABSTRACT

A metal-carbon particle composite material (30) is provided with one or more flake-like graphite particle dispersion layers (1) in which flake-like graphite particles (1a) as carbon particles are dispersed in a metal matrix (9), one or more carbon fiber dispersion layers (2) in which carbon fibers (2a) as carbon particles are dispersed in a metal matrix (9), and one or more metal layers (3) formed by the metal matrix (9) in a laminated manner. One or more flake-like graphite particle dispersion layers (1), one or more carbon fiber dispersion layers (2), and one or more metal layers (3) are integrally bonded. One of the flake-like graphite particle dispersion layer (1) and the carbon fiber dispersion layer (2) and the metal layer (3) are alternately laminated substantially entirely in the thickness direction of the composite material (30).

### TECHNICAL FIELD

The present invention relates to a metal-carbon particle composite material including a metal matrix and carbon particles dispersed in the metal matrix, a method of producing the same, and a cooling device for a power module.

Note that in this specification and claims, the term “aluminum” is used to include the meaning of both pure aluminum and aluminum alloy unless otherwise specified, and the term “copper” is used to include the meaning of both pure copper and a copper alloy unless otherwise specified.

Further note that although the vertical direction of the metal-carbon particle composite material according to the present invention is not limited, in this specification and claims, in order to make it easy to understand the composition of the composite material, the thickness direction of a composite material and the thickness direction of the laminate are defined as the vertical direction of the composite material and the vertical direction of the laminate, respectively.

Further note that although the vertical direction of the cooling device for a power module according to the present invention is not limited, in the present specification and claims, in order to make it easy to understand the structure of the cooling device, the mounting surface side of the cooling device on which the heat generating element (e.g., a power semiconductor chip) is mounted is defined as an upper side of the cooling device and the opposite side is defined as a lower side of the cooling device.

### BACKGROUND ART

As a document disclosing a metal-carbon particle composite material, for example, there are Japanese Patent No. 5150905 (Patent Document 1), Patent No. 4441768 (Patent Document 2), and Japanese Patent Application Publication No. 2006-1232 (Patent Document 3).

Japanese Patent No. 5150905 discloses a method of producing a metal-based carbon fiber composite material as a metal-carbon particle composite material in which a preform having a film containing carbon fibers as carbon particles formed on a sheet-like or foil-like metal support is formed, a plurality of the preforms are laminated to form a laminate, the laminates are heated and pressed to integrate the preforms. In this method, in the obtained composite material, the thermal conductivity becomes high only in one direction in which carbon fibers are arranged.

Japanese Patent No. 4441768 discloses a method of producing a metal-graphite composite material as a metal-carbon particle composite material by forming a sintered precursor using a mixture of flake-like graphite powder and predetermined flake-like metal powder and sintering the sintered precursor while pressurizing it. In this method, there are problems that it is difficult to handle the metal powder at the time of production and the manufacturing cost is high.

Japanese Unexamined Patent Application Publication No. 2006-1232 discloses a method of producing a high heat conduction/low thermal expansion composite material as a metal-carbon particle composite material by hot-press sintering the composite in which the crystalline carbon material layer and the metal layer are laminated and composited. In this method, it is considered that sintering of the composite is difficult, and hence bonding is insufficient and displacement of the bonding interface easily occurs.

As other documents disclosing a metal-carbon particle composite material, there are Japanese Unexamined Patent Application Publication No. 2015-25158 (Patent Document 4) and Japanese Unexamined Patent Application Publication No. 2015-217655 (Patent Document 5).

### PRIOR ART DOCUMENT

### Patent Document

Patent Document 1: Japanese Patent No. 5150905
Patent Document 2: Japanese Patent No. 4441768
Patent Document 3: Japanese Unexamined Patent Application Publication No. 2006-1232
Patent Document 4: Japanese Unexamined Patent Application Publication No. 2015-25158
Patent Document 5: Japanese Unexamined Patent Application Publication No. 2015-217655

### SUMMARY OF THE INVENTION

### Problems to be Solved by the Invention

Thus, a next generation semiconductor chip using SiC, etc., can operate at high temperature. The material of a cooling device for cooling such a chip has preferably a low linear expansion property to reduce thermal stress caused by an increase in operating temperature of the chip, and high thermal conductivity to enhance the cooling performance.

The present invention has been made in view of the aforementioned technical background, and aims to provide a metal-carbon particle composite material having high thermal conductivity and low linear expansion property, a method of producing the same, and a cooling device for a power module.

The other purposes and advantages of the present invention will be made apparent from the following preferred embodiments.

### Means for Solving the Problems

The present invention provides the following means.

[1] A metal-carbon particle composite material provided with one or more flake-like graphite particle dispersion layers in which flake-like graphite particles as carbon particles are dispersed in a metal matrix, one or more carbon fiber dispersion layers in which carbon fibers as carbon particles are dispersed in the metal matrix, and one or more metal layers formed of the metal matrix in a laminated manner,

wherein the one or more flake-like graphite particle dispersion layers, the one or more carbon fiber dispersion layers, and the one or more metal layers are integrally bonded, and

wherein one of the flake-like graphite particle dispersion layer and the carbon fiber dispersion layer and the metal layer are arranged in an alternately laminated manner substantially entirely in a thickness direction of the composite material.

[2] The metal-carbon particle composite material as recited in the aforementioned Item [1],

wherein the flake-like graphite particle dispersion layer, the carbon fiber dispersion layer, and the metal layer are arranged in a state of being laminated in a regular lamination order substantially entirely in the thickness direction of the composite material.

[3] A cooling device for a power module, comprising:

a plurality of cooling device constituent layers integrally bonded in a laminated manner,

wherein at least one of the plurality of cooling device constituent layers is made of the metal-carbon particle composite material as recited in the aforementioned Item [1] or [2].

[4] A method of producing a metal-carbon particle composite material, comprising:

a step of obtaining a flake-like graphite particle coated foil in which a flake-like graphite particle layer is formed on a first metal foil by coating a first coating liquid containing flake-like graphite particles as carbon particles and a first binder on the first metal foil and drying it;

a step of obtaining a carbon fiber coated foil in which a carbon fiber layer is formed on a second metal foil by coating a second coating liquid containing carbon fibers as carbon particles and a second binder on the second metal foil and drying it;

a step of forming a laminate in a state in which one or more flake-like graphite particle coated foils and one or more carbon fiber coated foils are laminated; and

a step of integrally bonding the one or more flake-like graphite particle coated foils and the one or more carbon fiber coated foils collectively by heating the laminate.

[5] The method of producing a metal-carbon particle composite material as recited in the aforementioned Item [4],

wherein in the step of forming the laminate, the laminate is formed such that the flake-like graphite particle coated foil and the carbon fiber coated foil are laminated in a regular lamination order substantially entirely in a thickness direction of the laminate.

### Effects of the Invention

The present invention has the following effects.

In the aforementioned Item [1], flake-like graphite particles are dispersed in the metal matrix, so that the thermal conductivity of the material is improved than that of the metal simple substance. Also, the carbon fibers are dispersed in the metal matrix, so that the linear expansion property of the material is lower than that of the metal simple substance. Therefore, the metal-carbon particle composite material as recited in the aforementioned Item [1] has high thermal conductivity (high thermal conductivity) and low linear expansion property (low linear expansion coefficient).

Further, one of the flake-like graphite particle dispersion layer and the carbon fiber dispersion layer and the metal layer are arranged in an alternately laminated manner substantially entirely in a thickness direction of the composite material. Therefore, the composite material has high bonding strength.

In the aforementioned Item [2], the flake-like graphite particle dispersion layer, the carbon fiber dispersion layer, and the metal layer are arranged in a state of being laminated in a regular lamination order substantially entirely in the thickness direction of the composite material. Therefore, by previously designing the volume ratio of flake-like graphite particles and carbon fibers contained in the metal matrix before producing the composite material and producing a composite material in a state in which a flake-like graphite particle dispersion layer, a carbon fiber dispersion layer, and a metal layer are laminated in a regular lamination order, the thermal conductivity and the linear expansion coefficient of the composite material can be brought closer to the design value.

In the aforementioned Item [3], at least one of the plurality of cooling device constituent layers is made of the metal-carbon particle composite material as recited in the aforementioned Item [1] or [2]. Therefore, it is possible to provide a cooling device for a power module having high heat dissipation and high cold heat reliability.

In the aforementioned Item [4], a metal-carbon particle composite material according to the present invention can be easily produced. Furthermore, by using a metal foil as the metal material of the metal matrix, handling of the metal material is easier and the manufacturing cost can be reduced as compared with the case in which metal powder is used. Furthermore, it is easy to control the thickness of the composite material, and it is easy to manufacture a thin composite material.

In the aforementioned Item [5], it exerts the same effects as the effects of the aforementioned Item [2].

### BRIEF DESCRIPTION OF THE DRAWINGS

FIG. 1 is a schematic cross-sectional view of a metal-carbon particle composite material according to a first embodiment of the present invention.

FIG. 2a is a schematic perspective view (left) of a flake-like graphite particle coated foil and its cross-sectional model diagram (right).

FIG. 2b is a schematic view for explaining a method of coating a first coating liquid on a first metal foil in a step of obtaining a flake-like graphite particle coated foil.

FIG. 3 is a schematic perspective view (left) of a carbon fiber coated foil and a cross-sectional model diagram (right) thereof.

FIG. 4 is a schematic cross-sectional model diagram of a laminate for forming the composite material.

FIG. 5 is a production step diagram of the composite material.

FIG. 6 is a schematic cross-sectional view of a metal-carbon particle composite material according to a second embodiment of the present invention.

FIG. 7 is a schematic cross-sectional model diagram of a laminate for forming the composite material.

FIG. 8 is a schematic cross-sectional view of a metal-carbon particle composite material according to a third embodiment of the present invention.

FIG. 9 is a schematic cross-sectional model diagram of a laminate for forming the composite material.

FIG. 10 is a schematic front view of a cooling device for a power module according to an embodiment of the present invention.

### EMBODIMENTS FOR CARRYING OUT THE INVENTION

Hereinafter, several embodiments of the present invention will be described with reference to the attached figures.

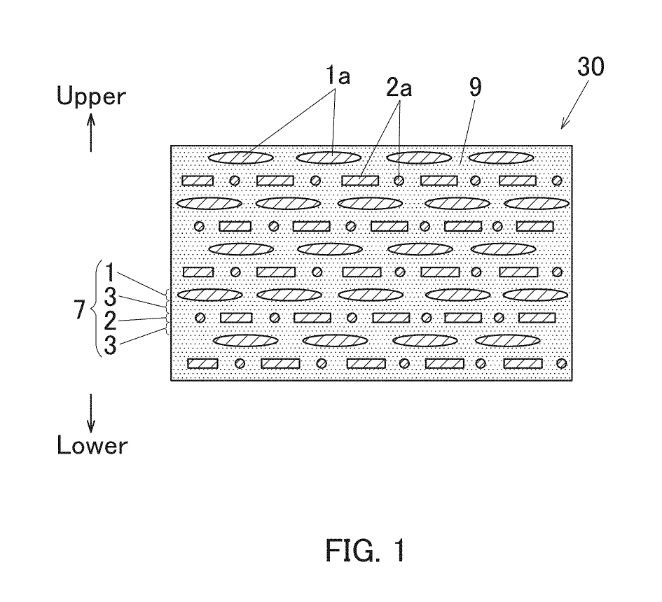

FIG. 1 to FIG. 5 are views for explaining a metal-carbon particle composite material according to a first embodiment of the present invention and a method of producing the same.

As shown in FIG. 1, the metal-carbon particle composite material 30 according to a first embodiment is provided with one or more flake-like graphite particle dispersion layers 1 in which flake-like graphite particles 1a as carbon particles are dispersed in a metal matrix (indicated by dot hatching) 9, one or more carbon fiber dispersion layers 2 in which carbon fibers 2a as carbon particles are dispersed in the metal matrix 9, and one or more metal layers 3 formed of the metal matrix 9 in a laminated manner.

Furthermore, one or more flake-like graphite particle dispersion layers 1, one or more carbon fiber dispersion layers 2, and one or more metal layers 3 are integrally bonded in a laminated manner. With this, a composite material 30 is formed. The composite material 30 is a kind of metal matrix carbon particle composite material.

In each flake-like graphite particle dispersion layer 1, there exists substantially no carbon fibers 2a. In each carbon fiber dispersion layer 2, there exists substantially no flake-like graphite particles 1a. In each metal layer 3, there exists substantially no flake-like graphite particles 1a and carbon fibers 2a.

Note that in FIG. 1 to FIG. 3, flake-like graphite particles 1a and carbon fibers 2a are largely illustrated to facilitate understanding of the configuration of the composite material 30.

In the first embodiment, as shown in FIG. 1, the number of flake-like graphite particle dispersion layer 1, the carbon fiber dispersion layer 2, and the metal layer 3 are plural. One of the flake-like graphite particle dispersion layer 1 and the carbon fiber dispersion layer 2 and the metal layer 3 are alternately laminated substantially entirely in the thickness direction (i.e., the vertical direction of the composite material 30) of the composite material 30.

Further, the flake-like graphite particle dispersion layer 1, the carbon fiber dispersion layer 2, and the metal layer 3 are arranged in a state of being laminated in a regular lamination order substantially entirely in the thickness direction of the composite material 30. More specifically, the flake-like graphite particle dispersion layer 1, the carbon fiber dispersion layer 2, and the metal layer 3 are arranged in a laminated manner according to the lamination rule that the unit of the lamination order for the flake-like graphite particle dispersion layer 1, the carbon fiber dispersion layer 2, and the metal layer 3 are repeated substantially entirely in the thickness direction of the composite material 30.

In the composite material 30 of the first embodiment, the unit 7 of the lamination order for the flake-like graphite particle dispersion layer 1, the carbon fiber dispersion layer 2, and the metal layer 3 is a unit called flake-like graphite particle dispersion layer 1/metal layer 3/carbon fiber dispersion layer 2/metal layer 3. The flake-like graphite particle dispersion layer 1, the carbon fiber dispersion layer 2, and the metal layer 3 are arranged in a laminated state in accordance with the lamination rule that this lamination order unit 7 is repeated entirely in the thickness direction of the composite material 30.

In the composite material 30, the layer number ratio of the flake-like graphite particle dispersion layer 1 and the carbon fiber dispersion layer 2 existing in the lamination order unit 7 is 1:1. The flake-like graphite particle dispersion layer 1 and the carbon fiber dispersion layer 2 are arranged entirely in the thickness direction of the composite material 30 with this layer number ratio.

Therefore, the layer number ratio of the flake-like graphite particle dispersion layer 1 and the carbon fiber dispersion layer 2 is constant irrespective of the portion in the thickness direction of the composite material 30. More specifically, the layer number ratio is 1:1 entirely in the total thickness direction of the composite material 30.

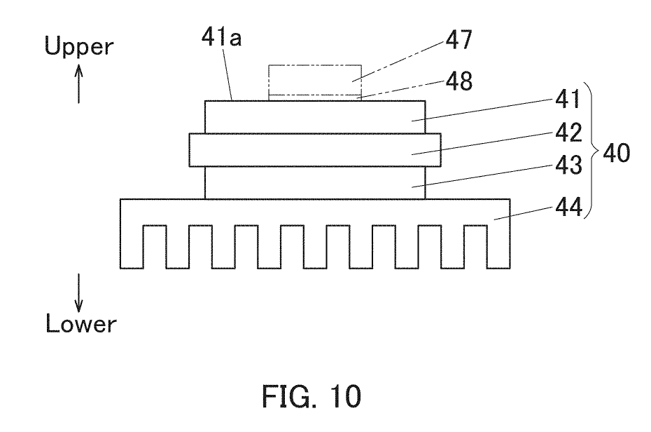

The composite material 30 of this first embodiment is suitably used as a material for at least one constituent layer among a plurality of cooling device constituent layers 41 to 44 constituting a cooling device for a power module 40 shown in FIG. 10.

A power module is used for vehicles, such as, e.g., a hybrid car (HEV), an electric vehicle (EV), a train, etc., and is used for energy fields, such as, e.g., wind power generation, solar power generation, etc.

The cooling device 40 is provided with a wiring layer 41, an insulating layer 42, a buffer layer 43, and a cooling layer 44 as a plurality of cooling device constituent layers 41 to 44. Then, from the top to the bottom, the coiling layer 41, the insulating layer 42, the buffer layer 43, and the cooling layer 44 are integrally bonded by a predetermined bonding means, such as, e.g., brazing, in a state in which the coiling layer 41, the insulating layer 42, the buffer layer 43 and the cooling layer 44 are laminated.

To the mounting surface 41a formed of the upper surface of the wiring layer 41, generally, a heat generating element (indicated by a two-dot chain line) 47, such as, e.g., a semiconductor element (e.g., power semiconductor chip), is bonded via a solder layer (indicated by a two-dot chain line) 48.

The insulating layer 42 has an electrical insulation property, and is usually formed of ceramic.

The buffer layer 43 is a layer for relieving stress, such as, e.g., thermal stress, generated in the cooling device 40.

The cooling layer 44 is a layer for cooling the heat generating element 47 by dissipating the heat of the heat generating element 47, and is formed of, for example, a heat sink having a plurality of heat dissipating fins.

In the cooling device 40 shown in FIG. 10, more specifically, at least one member selected from the group consisting of the constituent layers (i.e., the capacitor layer 41, the buffer layer 43, and the cooling layer 44) except for the insulating layer 42 among the plurality of constituent layers 41 to 44 is made of the composite material 30 of the first embodiment. In general, the cooling device 40 is required to have high heat dissipation and high cold heat reliability against a cold heat cycle load.

Next, a preferable method of producing the composite material 30 of the first embodiment will be described below.

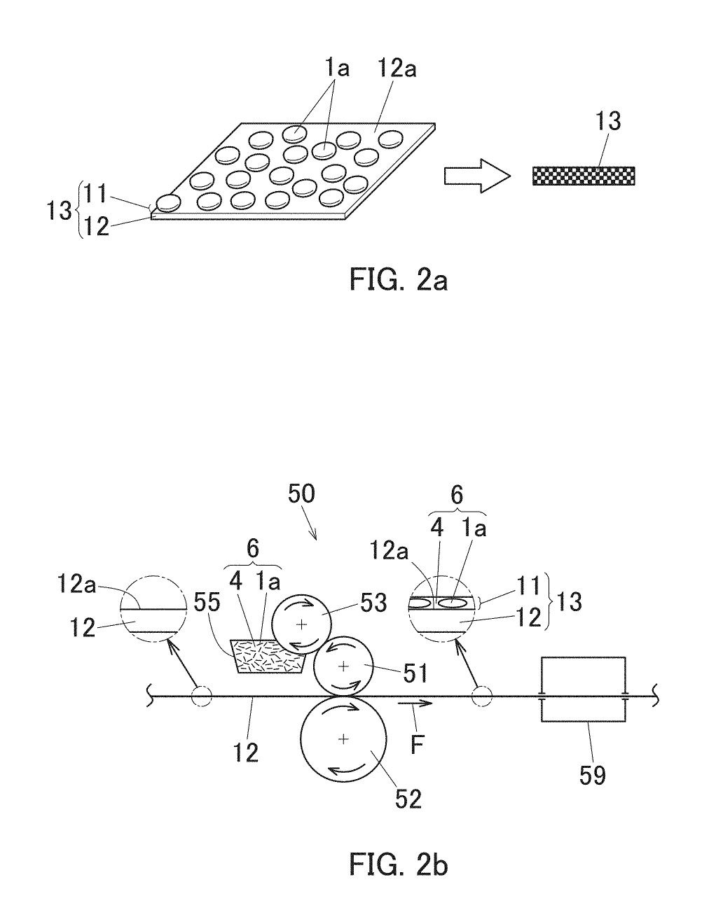

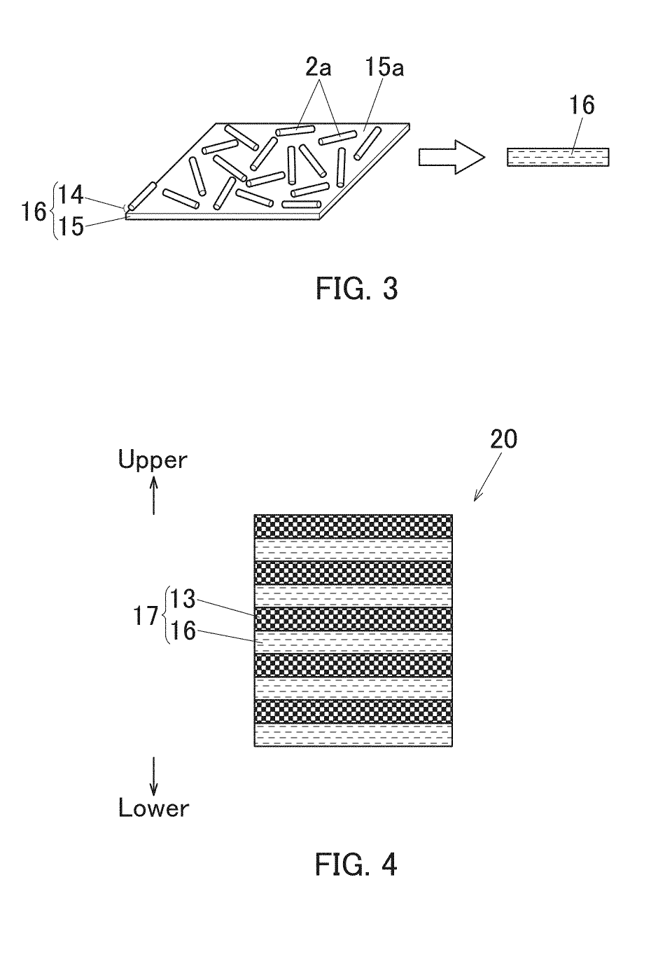

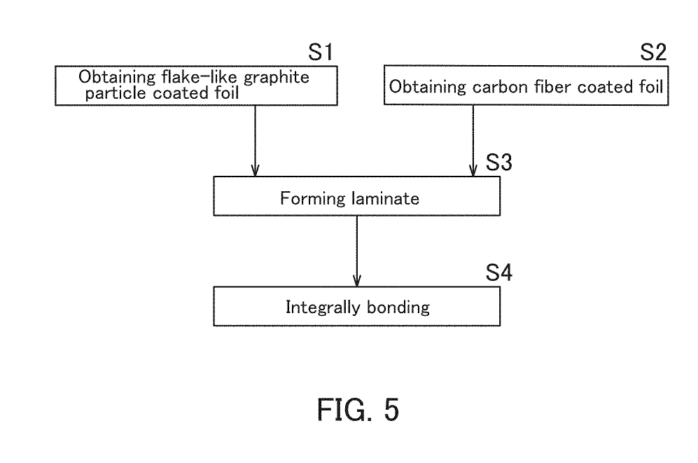

As shown in FIG. 5, the method of producing the composite material 30 includes Step S1 (see FIG. 2a and FIG. 2b) of obtaining a flake-like graphite particle coated foil 13 in which a flake-like graphite particle layer 11 as a carbon particle layer is formed on a first metal foil 12, Step S2 (see FIG. 3) of obtaining a carbon fiber coated foil 16 in which a carbon fiber layer 14 as a carbon particles layer is formed on a second metal foil 15, Step S3 (see FIG. 4) of forming a laminate 20 in a state in which one or more flake-like graphite particle coated foils 13 and one or more carbon fiber coated foils 16 are laminated, and Step S4 of collectively integrally bonding one or more flake-like graphite particle coated foils 13 and one or more carbon fiber coated foils 16 by heating the laminate 20.

In FIG. 2a and FIG. 3, the metallic materials of the first and second metal foils 12 and 15 form the metal matrix 9 of the composite material 30. The metal material of the first metal foil 12 and the metal material of the second metal foil 15 are the same material. The metal material is not limited, but it is desirable that the metal material be aluminum or copper. The reason is that these metals have high thermal conductivity.

The thicknesses of the first and second metal foils 12 and 15 are not limited, and are preferably 5 to 500 μm, more preferably 10 to 50 μm, respectively.

As shown in FIG. 2a, as the flake-like graphite particles 1a, for example, a flake-like graphite powder can be used. The particle diameter and the aspect ratio of the flake-like graphite particle 1a are not limited, and it is preferable that each be as large as possible. The average particle diameter of the flake-like graphite particle 1a is particularly preferably 300 μm or more, and the average aspect ratio of the flake-like graphite particle 1a is particularly preferably 30 or more. The upper limit of the average particle diameter is not limited, but is, for example, 1,000 μm, and the upper limit of the average aspect ratio is not limited, and is, for example, 100.

Here, the particle diameter of the flake-like graphite particles 1a means the circle equivalent diameter of the flake-like graphite particles 1a in the plane direction observed by an observation means, such as, e.g., an electron microscope. The aspect ratio of the flake-like graphite particles 1a is calculated by the “particle diameter/thickness” of the flake-like graphite particle 1a. Note that the plane direction of the flake-like graphite particle 1a described above means a plane direction perpendicular to the thickness direction of the flake-like graphite particle 1a.

As shown in FIG. 3, as the carbon fiber 2a, fibrous carbon particles can be used, specifically, for example, one kind of carbon fiber or a mixed carbon fiber of plural kinds selected from the group consisting of a pitch based carbon fiber, a PAN based carbon fiber, a vapor phase grown carbon fiber, and a carbon nanotube can be used. It is particularly preferable that the carbon fiber 2a is a pitch based carbon fiber. The reason is that the thermal conductivity of the pitch based carbon fiber is larger than that of the PAN based carbon fiber.

The length of the carbon fiber 2a is not limited, and it is particularly preferable that the average fiber length of carbon fiber 2a be 1 mm or less. The lower limit of the average length of the carbon fiber 2a is not limited and is, for example, 10 μm.

The flake-like graphite particle 1a and the carbon fiber 2a may be heat treated at a temperature of 2,000 to 3,000° C. in an inert atmosphere.

In Step S1 of obtaining the flake-like graphite particle coated foil 13, the flake-like graphite particle coated foil 13 shown in FIG. 2a is obtained by coating a first coating liquid (not shown) containing flake-like graphite particles 1a, a first binder (not shown), and a first solvent for the first binder (not shown) in a mixed state on the first metal foil 12 and drying it. In the left side of FIG. 2a, the first binder is not illustrated.

In Step S2 of obtaining the carbon fiber coated foil 16, the carbon fiber coated foil 16 shown in FIG. 3 is obtained by coating a second coating liquid (not shown) containing a carbon fiber 2a, a second binder (not shown), and a second solvent for the second binder (not shown) in a mixed state on the second metal foil 15 and drying it. On the left side In FIG. 3, the second binder is not illustrated.

The first binder is for suppressing the flake-like graphite particle 1a from falling off the first metal foil 12 by imparting adhesive force to the first metal foil 12 with respect to the flake-like graphite particle 1a.

The second binder is for suppressing the carbon fiber 2a from falling off the second metal foil 15 by imparting adhesion force to the second metal foil 15 with respect to the carbon fiber 2a.

The first and second binders are usually made of resin. Specifically, as the first and second binder, an acryl based resin, a polyethylene glycol based resin, a butylene rubber resin, a phenol resin, a cellulose based resin, etc., can be used. These resin binders are generally solid at ambient temperature.

The first solvent dissolves the first binder. The second solvent dissolves the second binder. Specifically, as the first and second solvents, water, an alcohol based solvent, a hydrocarbon based solvent, an ester based solvent, an ether based solvent, etc., can be used. These solvents can generally dissolve a binder at ambient temperature.

The first coating liquid is obtained by mixing the flake-like graphite particles 1a, the first binder, and the first solvent.

The method of coating the first coating liquid on the first metal foil 12 is not limited. Preferably, the coating of the first coating liquid is performed by a roll-to-roll method as disclosed in Japanese Unexamined Patent Application Publication Nos. 2015-25158 and 2015-217655. The coating method of the first coating liquid is preferably selected from an offset type three roll coating method (that is, a coating method using an offset type three roll coater), a gravure printing method, a spray coating method, a curtain coating method, etc.

An example of a coating method of the first coating liquid will be described below with reference to FIG. 2b.

As shown in the figure, the coating apparatus 50 for coating the first coating liquid on the first metal foil is an apparatus adopting a roll-to-roll system, and is provided with an applicator roll 51, a backup roll 52, a pickup roll 53, a pan 55, etc. In the pan 55, a first coating liquid 6 is contained. The first coating liquid 6 contains the flake-like graphite particles 1a, the first binder 4, and the first solvent in a mixed state, and the first binder 4 is dissolved in the first solvent.

The first metal foil 12 is fed in a predetermined direction F so as to pass between the applicator roll 51 and the backup roll 52. The first coating liquid 6 in the pan 55 is adhered to the applicator roll 51 by the pickup roller 53 and is coated on the first metal foil 12 by the applicator roll 51 in a layered manner.

In Step S1 of obtaining the flake-like graphite particle coated foil 13, specifically, the first coating liquid 6 is coated to substantially entirely the entire surface 12a on one side of the first metal foil 12 in the thickness direction. Next, the first coating liquid 6 is dried by a predetermined drying means (e.g., a drying furnace 59) so that the first solvent in the first coating liquid 6 is evaporated and removed. Thereafter, as the need arises, the first metal foil 12 is cut into a predetermined shape (e.g., square shape). With this, the flake-like graphite particle coated foil 13 shown in FIG. 2a is obtained. As described above, the first binder 4 is not shown on the left side of FIG. 2a.

In the first embodiment, the surface 12a of the first metal foil 12 to which the first coating liquid 6 is coated is the upper surface of the first metal foil 12 in a state in which the first metal foil 12 is horizontally disposed. Therefore, specifically, the flake-like graphite particle layer 11 is formed substantially entirely on the upper surface 12a of the first metal foil 12.

The second coating liquid is obtained by mixing the carbon fiber 2a, the second binder, and the second solvent.

The method of coating the second coating liquid on the second metal foil 15 is not limited. Preferably, the coating of the second coating liquid is performed by a roll-to-roll method as disclosed in Japanese Unexamined Patent Application Publication Nos. 2015-25158 and 2015-217655. The coating method of the second coating liquid is preferably selected from a gravure printing method, a bar coating method, a knife coating method, a doctor blade method, etc.

The coating of the second coating liquid is performed by, for example, the same method as the above-described coating method of the first coating liquid 6 shown in FIG. 2b.

In Step S2 of obtaining the carbon fiber coated foil 16, more specifically, the second coating liquid is coated substantially entirely on the entire surface 15a of the second metal foil 15 which is one side in the thickness direction of the second metal foil 15. Then, the second coating liquid is dried by a predetermined drying means (e.g., drying furnace) so that the second solvent in the second coating liquid is evaporated and removed. After that, as the need arises, the second metal foil is cut into a predetermined shape (e.g., square shape). With this, the carbon fiber coated foil 16 shown in FIG. 3 is obtained. Note that as described above, the second binder is not illustrated on the left side of FIG. 3.

In the first embodiment, the surface 15a of the second metal foil 15 to which the second coating liquid is coated is the upper surface of the second metal foil 15 in a state in which the second metal foil 15 is horizontally arranged. Therefore, specifically, the carbon fiber layer 14 is formed substantially entirely on the upper surface 15a of the second metal foil 15.

In Step S3 of forming the laminate 20, as shown in FIG. 4, as described above, the laminate 20 is a laminate in which one or more flake-like graphite particle coated foils 13 and one or more carbon fiber coated foils 16 are laminated. More specifically, the laminate 20 is a laminate in a state in which a plurality of flake-like graphite particle coated foils 13 and a plurality of carbon fiber coated foils 16 are laminated in the vertical direction so that the first metal foil 12 or the second metal foil 15 necessarily intervenes between carbon particles layers (flake-like graphite particle layer 11, carbon fiber layer 14). Therefore, in the entire laminate 20, a plurality of flake-like graphite particle coated foils 13 and a plurality of carbon fiber coated foils 16 are laminated so that the carbon particle layers are not superimposed.

In Step S3 of forming the laminate 20, the laminate 20 is formed so that the flake-like graphite particle coated foil 13 and the carbon fiber coated foil 16 are laminated entirely in the thickness direction of the laminate 20 (that is, the vertical direction of the laminate 20) in a regular lamination order. More specifically, the flake-like graphite particle coated foil 13 and the carbon fiber coated foil 16 are laminated in accordance with the lamination rule that the unit of lamination order for the flake-like graphite particle coated foil 13 and the carbon fiber coated foil 16 are repeated entirely in the thickness direction of the laminate 20. With this, the laminate 20 is formed.

In the laminate 20 of the first embodiment, the unit 17 of lamination order for the flake-like graphite particle coated foil 13 and the carbon fiber coated foil 16 is a unit of “flake-like graphite particle coated foil 13/carbon fiber coated foil 16”. The flake-like graphite particle coated foil 13 and the carbon fiber coated foil 16 are laminated in accordance with the lamination rule that this lamination order unit 17 is repeated entirely in the entire thickness direction of the laminate 20. With this, the laminate 20 is formed.

The number ratio of the flake-like graphite particle coated foil 13 and the carbon fiber coated foil 16 existing in the lamination order unit 17 is 1:1. The flake-like graphite particle coated foil 13 and the carbon fiber coated foil 16 are arranged entirely in the thickness of the laminate 20 at this number ratio.

Therefore, the number ratio of the flake-like graphite particle coated foil 13 and the carbon fiber coated foils 16 is constant irrespective of the position in the thickness direction of the laminate 20. More specifically, it is constant entirely 1:1 in the thickness direction of the laminate 20.

In Step S4 of integrally bonding foils, the laminate 20 is sintered by being heated in a predetermined sintering atmosphere (e.g., non-oxidizing atmosphere). With this, a plurality of flake-like graphite particle coated foils 13 and a plurality of carbon fiber coated foils 16 existing in the entire laminate 20 are collectively integrally bonded (specifically, integrally sintered). With this, the aforementioned composite material 30 is obtained.

The sintering method of the laminate 20 is selected from a vacuum hot press method, a pulse energization sintering method (SPS method), a hot isostatic pressing method (HIP method), an extrusion method, a rolling method, and the like.

When heating the laminate 20, it is desirable to heat the laminate 20 while pressing the laminate 20 in its thickness direction (that is, the lamination direction of the flake-like graphite particle coated foil 13 and the carbon fiber coated foil 16). This is because the laminate 20 can be strongly sintered.

The heating temperature (i.e., sintering temperature of the laminate 20) of the laminate 20 for sintering the laminate 20 is not limited. Usually, the heating temperature is equal to or less than the melting point of the metallic material of the first and second metal foils 12 and 15. In particular, it is desirable to set the temperature between the melting point of the metallic material and the temperature about 50° C. lower than the melting point. This is because the laminate 20 can be assuredly sintered. Specifically, when the metallic material is, for example, aluminum, the heating temperature (sintering temperature) of the laminate 20 is preferably set within the range of 550 to 620° C.

The first and second binders existing in the laminate 20 disappears by sublimation, decomposition, etc., and is removed from the laminate 20 in the course of heating the laminate 20 so that the temperature of the laminate 20 rises from approximately room temperature to the temperature at which the laminate 20 is sintered in Step S4 of integrally bonding them.

In Step S4 of integrally bonding them, the laminate 20 is heated. With this, some of the metallic materials of the first and second metal foils 12 and 15 penetrates into the respective flake-like graphite particle layer 11 and carbon fiber layer 14 to be filled in fine voids existing in the respective layers 11 and 14 (e.g., a gap between the flake-like graphite particles 1a in the flake-like graphite particle layer 11 and a gap between the carbon fibers 2a in the carbon fiber layer 14), so that the voids are substantially eliminated. With this, the bonding strength (sintering strength) between the flake-like graphite particle coated foil 13 and the carbon fiber coated foil 16 improves and the density of the composite material 30 increases.

Further, some of the metallic material of the first and second metal foils 12 and 15 penetrates into the flake-like graphite particle layer 11, so that it becomes a state in which the flake-like graphite particles 1a in the flake-like graphite particle layer 11 are dispersed in the metal matrix 9 of the composite material 30. That is, the flake-like graphite particle layer 11 becomes the flake-like graphite particle dispersion layer 1 of the composite material 30.

Further, some of the metallic material of the first and second metal foils 12 and 15 penetrates into the carbon fiber layer 14, so that the carbon fiber 2a in the carbon fiber layer 14 is dispersed in the metal matrix 9 of the composite material 30. That is, the carbon fiber layer 14 becomes the carbon fiber dispersion layer 2 of the composite material 30.

Further, the first and second metal foils 12 and 15 become the metal layers of the composite material 30.

Therefore, in the composite material 30, as shown in FIG. 1, one of the flake-like graphite particle dispersion layer 1 and the carbon fiber dispersion layer 2 and the metal layer 3 are arranged in a state of being alternately laminated. In the first embodiment, more specifically, the metal layer 3 is necessarily interposed between the flake-like graphite particle dispersion layer 1 and the carbon fiber dispersion layer 2.

In the composite material 30 of the first embodiment, as shown in FIG. 1, the flake-like graphite particles 1a are dispersed in the metal matrix 9, so that the composite material 30 has high thermal conductivity, and the carbon fibers 2a are dispersed in the metal matrix 9, so that the composite material has low linear expansion coefficient.

Furthermore, since one of the flake-like graphite particle dispersion layer 1 and the carbon fiber dispersion layer 2 and the metal layer 3 are arranged in a state of being alternately laminated, as compared with the case in which the flake-like graphite particle dispersion layer 1 and the carbon fiber dispersion layer 2 are arranged in a state of being laminated without interposing the metal layer 3 between the two layers 1 and 2, the composite material 30 has high bonding strength (high sintering strength).

Further, the flake-like graphite particle dispersion layer 1, the carbon fiber dispersion layer 2, and the metal layer 3 are arranged in a state of being laminated in a regular lamination order substantially entirely in the thickness direction of the composite material 30. Therefore, prior to producing the composite material 30, by previously designing the volume ratio of the flake-like graphite particles 1a and the carbon fiber 2a contained in the metal matrix 9, and by producing the composite material 30 with these layers laminated in a regular lamination order, a composite material 30 having thermal conductivity and linear expansion coefficient close to the design value can be easily obtained.

The method of producing the composite material 30 of the first embodiment has the following advantages.

That is, it is technically difficult to form a mixed layer of flake-like graphite particles 1a and carbon fibers 2a on a metal foil. Therefore, in the first embodiment, the flake-like graphite particle layer 11 is formed on the first metal foil 12, and the carbon fiber layer 14 is formed on the second metal foil 15 different from the first metal foil 12. By doing so, the composite material 30 can be easily produced.

Furthermore, since a metal foil is used as the metallic material of the metal matrix 9, handling is easier and the production cost becomes cheaper as compared with the case in which metal powder is used. Furthermore, it is easy to control the thickness of the composite material 30, and it is easy to produce a thin composite material.

Further, in the cooling device 40 for a power module (see FIG. 10), since at least one of the plurality of cooling device constituent layers 41 to 44 is made of the composite material 30 of the first embodiment, the cooling device 40 has high heat dissipation and high cold heat reliability.

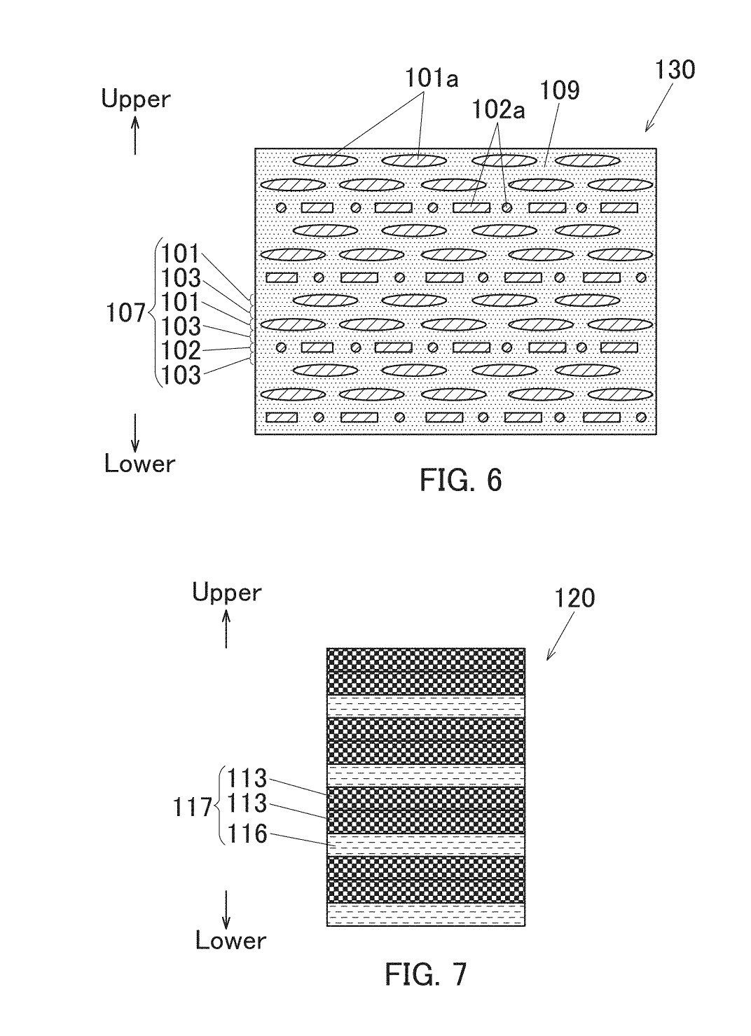

FIG. 6 and FIG. 7 are views for explaining a metal-carbon particle composite material 130 according to a second embodiment of the present invention and a method of producing the same. In these figures, an element having the same function as the element of the composite material 30 of the first embodiment is allotted by a reference numeral obtained by adding 100 to the reference numeral allotted to the element of the composite material 30 of the first embodiment. Hereinafter, the second embodiment will be described focusing on the points different from those of the first embodiment.

As shown in FIG. 6, in the composite material 130 of the second embodiment, the unit 107 of the lamination order for the flake-like graphite particle dispersion layer 101, the carbon fiber dispersion layer 102, and the metal layer 103 is a unit called flake-like graphite particle dispersion layer 101/metal layer 103/flake-like graphite particle dispersion layer 101/metal layer 103/carbon fiber dispersion layer 102/metal layer 103. The flake-like graphite particle dispersion layer 101, the carbon fiber dispersion layer 102, and the metal layer 103 are arranged in a laminated state in accordance with the lamination rule that this lamination order unit 107 is repeated entirely in the thickness direction of the composite material 130.

In the composite material 130, the layer number ratio of the flake-like graphite particle dispersion layer 101 and the carbon fiber dispersion layer 102 existing in the lamination order unit 107 is 2:1. The flake-like graphite particle dispersion layer 101 and the carbon fiber dispersion layer 102 are arranged at this layer number ratio entirely in the thickness direction of the composite material 130.

Therefore, the layer number ratio of the flake-like graphite particle dispersion layer 101 and the carbon fiber dispersion layer 102 is constant irrespective of the position in the thickness direction of the composite material 130. More specifically, it is 2:1 entirely in the thickness direction of the composite material 130.

As shown in FIG. 7, in Step S3 (see FIG. 5) of forming the laminate 120 in the second embodiment, the laminate 120 is formed such that the flake-like graphite particle coated foil 113 and the carbon fiber coated foil 116 are laminated in a regular lamination order entirely in the thickness direction of the laminate 120.

The unit 117 of the lamination order for the flake-like graphite particle coated foil 113 and the carbon fiber coated foil 116 is a unit called flake-like graphite particle coated foil 113/flake-like graphite particles coated foil 113/carbon fiber coated foil 116. The flake-like graphite particle coated foil 113 and the carbon fiber coated foil 116 are laminated in accordance with the lamination rule that this lamination order unit 117 is repeated entirely in the thickness direction of the laminate 120. With this, the laminate 120 is formed.

The number ratio of the flake-like graphite particle coated foil 113 and the carbon fiber coated foil 116 existing in the lamination order unit 117 is 2:1. The flake-like graphite particle coated foil 113 and the carbon fiber coated foil 116 are arranged entirely in the thickness of the laminate 120 at this number ratio.

Therefore, the number ratio of the flake-like graphite particle coated foil 113 and the carbon fiber coated foil 116 is constant irrespective of the position in the thickness direction of the laminate 120. More specifically, it is constant 2:1 entirely in the thickness direction of the laminate 120.

In the same manner as in the composite material 30 of the first embodiment, the composite material 130 of the second embodiment can be suitably used as a material of at least one constituent layer among the plurality of cooling device constituent layers 41 to 44 constituting the cooling device 40 for a power module shown in FIG. 10.

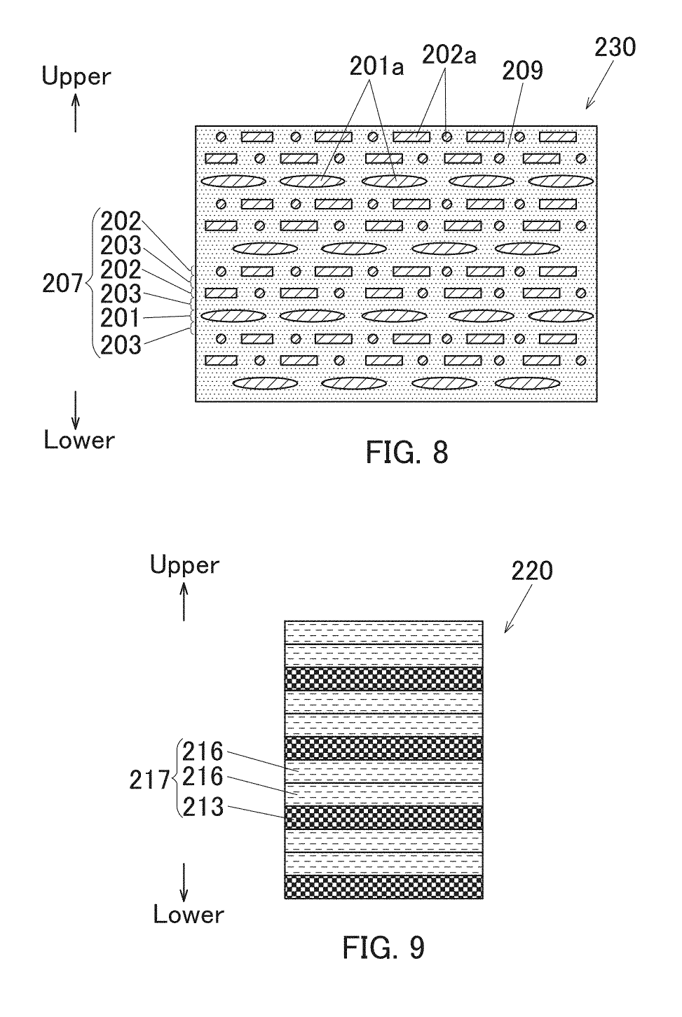

FIG. 8 and FIG. 9 are views for explaining a metal-carbon particle composite material 230 according to a third embodiment of the present invention and a method of producing the same. In these figures, an element having the same function as the element of the composite material 30 of the first embodiment is allotted by a reference numeral obtained by adding 200 to the reference numeral allotted to the element of the composite material 30 of the first embodiment. Hereinafter, the third embodiment will be described focusing on the points different from those of the first embodiment.

As shown in FIG. 8, in the composite material 230 of the third embodiment, a unit 207 of the lamination order for the flake-like graphite particle dispersion layer 201, the carbon fiber dispersion layer 202, and the metal layer 203 is a unit called carbon fiber dispersion layer 202/metal layer 203/carbon fiber dispersion layer 202/metal layer 203/flake-like graphite particle dispersion layer 201/metal layer 203. The flake-like graphite particle dispersion layer 201, the carbon fiber dispersion layer 202, and the metal layer 203 are arranged in a laminated state in accordance with the lamination rule that this lamination order unit 207 is repeated entirely in the thickness direction of the composite material 230.

In the composite material 230, the layer number ratio of the flake-like graphite particle dispersion layer 201 and the carbon fiber dispersion layer 202 existing in the lamination order unit 207 is 1:2. The flake-like graphite particle dispersion layer 201 and the carbon fiber dispersion layer 202 are arranged at this layer number ratio entirely in the thickness direction of the composite material 230.

Therefore, the layer number ratio of the flake-like graphite particle dispersion layer 201 and the carbon fiber dispersion layer 202 is constant irrespective of the position in the thickness direction of the composite material 230. More specifically, it is 1:2 entirely in the thickness direction of the composite material 230.

As shown in FIG. 9, in Step S3 (see FIG. 5) of forming the laminate 220 in the third embodiment, the laminate 220 is formed such that the flake-like graphite particle coated foil 213 and the carbon fiber coated foil 216 are laminated in a regular lamination order entirely in the thickness direction of the laminate 220.

The unit 217 of the lamination order for the flake-like graphite particle coated foil 213 and the carbon fiber coated foil 216 is a unit called carbon fiber coated foil 216/carbon fiber coated foil 216/flake-like particle coated foil 213. The flake-like graphite particle coated foil 213 and the carbon fiber coated foil 216 are laminated in accordance with the lamination rule that this lamination order unit 217 is repeated entirely in the thickness direction of the laminate 220. With this, the laminate 220 is formed.

The number ratio of the flake-like graphite particle coated foil 213 and the carbon fiber coated foil 216 existing in the lamination order unit 217 is 1:2. The flake-like graphite particle coated foil 213 and the carbon fiber coated foil 216 are arranged entirely in the thickness of the laminate 220 at this number ratio.

Therefore, the number ratio of the flake-like graphite particle coated foil 213 and the carbon fiber coated foil 216 is constant irrespective of the position in the thickness direction of the laminate 220. More specifically, it is constant 1:2 entirely in the thickness direction of the laminate 220.

In the same manner as in the composite material 30 of the first embodiment, the composite material 230 of the third embodiment can be suitably used as a material of at least one constituent layer among the plurality of cooling device constituent layers 41 to 44 constituting the cooling device 40 for a power module shown in FIG. 10.

Although several embodiments of the present invention are described above, the present invention is not limited to the aforementioned embodiments, and various modifications can be made within the scope not departing from the gist of the present invention.

In the present invention, the layer number ratio of the flake-like graphite particle dispersion layer and the carbon fiber dispersion layer present in the lamination order unit in the composite material is not limited to 1:1 (first embodiment), 2:1 (second embodiment), and 1:2 (third embodiment), but may be other layer number ratio. It is usually set in the range of 1 to 10:1 to 10.

In the present invention, in the Step of forming the laminate, the laminate may be a laminate made by laminating a long flake-like graphite particle coated foil (for example, a strip of flake-like graphite particle coated foil) and a long carbon fiber coated foil (for example, a strip of carbon fiber coated foil) in a state of being wound plural times in a roll state.

The metal-carbon particle composite material according to the present invention is preferably produced by the production method described in the first embodiment (including the second and third embodiments) in the point that the bonding strength of the composite material (sintering strength) can be readily and reliably increased, but it may be produced by the following production method.

That is, in the step of obtaining a flake-like graphite particle coated foil, by coating the first coating liquid on both surfaces of the first metal foil in the thickness direction, respectively, and drying them, a flake-like graphite particle coated foil (for convenience, referred to as “flake-like graphite particle double-sided coated foil”) having flake-like graphite particle layers formed on the surfaces of both sides in the thickness direction of the first metal foil is obtained. Further, in the step of obtaining a carbon fiber coated foil, by coating the second coating liquid on both surfaces in the thickness direction of the second metal foil, respectively, and drying them, a carbon fiber coated foil (referred to as “carbon fiber double-sided coated foil” for convenience) having carbon fiber layers formed on the surfaces of both sides in the thickness direction of the second metal foil is obtained.

Further, by coating the first coating liquid on one of the surfaces of both sides in the thickness direction of the metal foil and the second coating liquid on the other surface and drying them, a coated foil in which a flake-like graphite particle layer is formed on one of the surfaces of both sides in the thickness direction of the metal foil and a carbon fiber layer is formed on the other surface (for convenience, “flake-like graphite particle/carbon fiber double-sided coated foil”) may be obtained.

In the case of producing the composite material using the above-described double-sided coated foil (that is, “flake-like graphite particle double-sided coated foil”, “carbon fiber double-sided coated foil”, and “flake-like graphite particle/carbon fiber double-sided coated foil”, in the step of forming a laminate, when a plurality of double-sided coated foils are laminated in a state in which carbon particle layers (flake-like graphite particle layers, carbon fiber layers) are laminated with each other, in the step of integrally bonding them, there is a possibility that poor bonding (sintering failure) may occur at the lamination interface between the carbon particles layers. Therefore, in order to suppress this poor bonding, it is desirable to interpose a metal foil between each double-sided coated foil when laminating a plurality of double-sided coated foils. By doing so, some of the metallic material of the metal foil penetrates into the carbon particle layers arranged on both sides in the thickness direction thereof in the step of integrally bonding them. Therefore, it is possible to assuredly increase the bonding strength (sintering strength) of the obtained composite material.

However, as described in the first embodiment (including the second and third embodiments), it is preferable to obtain a flake-like graphite particle coated foil 13 (this is referred to as “flake-like graphite particle single-sided coated foil 13” for convenience) having a flake-like graphite particle layer 11 formed on the surface 12a of one side in the thickness direction of the first metal foil 12 by coating the first coating liquid on the surface 12a of one side in the thickness direction of the first metal foil 12 and drying it, and also preferable to obtain a carbon fiber coated foil 16 (this is referred to as “carbon fiber single-sided coated foil 16” for convenience) having a carbon fiber layer 14 formed on the surface 15a of one side in the thickness direction of the second metal foil 15 by coating the second coating liquid on the surface 15a of one side in the thickness direction of the second metal foil 15 and drying it. The reason is as follows.

That is, as described in the first embodiment (including the second and third embodiments), in the case of producing the composite material 30 by using the above-mentioned single-sided coated foil (that is, “flake-like graphite particle single-sided coated foil 13”, “carbon fiber single-sided coated foil 16”), in Step S3 of forming the laminate 20, a plurality of single-sided coated foils 13 and 16 can be laminated so that the carbon particle layer (flake-like graphite particle layer 11, carbon fiber layer 14) is not overlapped. Therefore, there is no need to interpose a metal foil between the single-sided coated foils 13 and 16 when laminating a plurality of single-sided coated foils 13 and 16. Therefore, it is possible to easily and assuredly increase the bonding strength (sintering strength) of the obtained composite material 30.

Further, the metal-carbon particle composite material according to the present invention can be used not only as a material for a cooling device for a power module but also as a material for other usages.

The present application claims priority to Japanese Patent Application No. 2016-220386 filed on Nov. 11, 2016, the entire disclosure of which is incorporated herein by reference in its entirety.

It should be understood that the terms and expressions used herein are used for explanation and have no intention to be used to construe in a limited manner, do not eliminate any equivalents of features shown and mentioned herein, and allow various modifications falling within the claimed scope of the present invention.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. Limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features.

### INDUSTRIAL APPLICABILITY

The present invention is applicable to a metal-carbon particle composite material including a metal matrix and carbon particles (flake-like graphite particles and carbon fibers) dispersed in the metal matrix, a method of producing the same, and a cooling device for a power module.

Description of Reference Symbols
1, 101, 201 flake-like graphite particle dispersion layer
1a, 101a, 201a flake-like graphite particle
2, 102, 202 carbon fiber dispersion layer
2a, 102a, 202a carbon fiber
3, 103, 203 metal layer
9, 109, 209 metal matrix
11 flake-like graphite particle layer
12 first metal foil
13, 113, 213 flake-like graphite particle coated foil
14 carbon fiber layer
15 second metal foil
16, 116, 216 carbon fiber coated foil
20, 120, 220 laminate
30, 130, 230 metal-carbon particle composite material
40 cooling device for a power module

1-5. (canceled)

6. A metal-carbon particle composite material in which one or more flake-like graphite particle dispersion layers in which flake-like graphite particles as carbon particles are dispersed in a metal matrix, one or more carbon fiber dispersion layers in which carbon fibers as carbon particles are dispersed in the metal matrix, and one or more metal layers formed of the metal matrix are integrally bonded in a laminated manner.

7. The metal-carbon particle composite material as recited in claim 6,
wherein the flake-like graphite particle dispersion layer, the carbon fiber dispersion layer, and the metal layer are arranged in a state of being laminated in a regular lamination order substantially entirely in a thickness direction of the composite material.

8. A cooling device for a power module, comprising:
a plurality of cooling device constituent layers integrally bonded in a laminated manner,
wherein at least one of the plurality of cooling device constituent layers is made of the metal-carbon particle composite material as recited in claim 6.

9. A method of producing a metal-carbon particle composite material, comprising:
a step of obtaining a flake-like graphite particle coated foil in which a flake-like graphite particle layer is formed on a first metal foil by coating a first coating liquid containing flake-like graphite particles as carbon particles and a first binder on the first metal foil and drying it;
a step of obtaining a carbon fiber coated foil in which a carbon fiber layer is formed on a second metal foil by coating a second coating liquid containing carbon fibers as carbon particles and a second binder on the second metal foil and drying it;
a step of forming a laminate in a state in which one or more flake-like graphite particle coated foils and one or more carbon fiber coated foils are laminated; and
a step of integrally bonding the one or more flake-like graphite particle coated foils and the one or more carbon fiber coated foils collectively by heating the laminate.

10. The method of producing a metal-carbon particle composite material as recited in claim 9,
wherein in the step of forming the laminate, the laminate is formed such that the flake-like graphite particle coated foil and the carbon fiber coated foil are laminated in a regular lamination order substantially entirely in a thickness direction of the laminate.
